(19) United States
(12) Patent Application Publication
(10) Pub. No.: US 2019/0295888 A1
(43) Pub. Date: Sep. 26, 2019

(54) SEMICONDUCTOR DEVICE AND METHOD FOR MANUFACTURING THE SAME

(71) Applicants: Kabushiki Kaisha Toshiba, Tokyo (JP); Toshiba Electronic Devices & Storage Corporation, Tokyo (JP)

(72) Inventors: Takahito Nakajima, Oita Oita (JP); Shinya Ito, Oita Oita (JP); Masaru Hatano, Oita Oita (JP)

(21) Appl. No.: 16/137,789

(22) Filed: Sep. 21, 2018

(30) Foreign Application Priority Data
Mar. 23, 2018 (JP) 2018-055447

(51) Int. Cl. H01L 21/768; H01L 23/535; H01L 23/532; H01L 21/311

(52) U.S. Cl. CPC H01L 21/76895; H01L 23/535; H01L 21/76805; H01L 23/5329; H01L 21/31116; H01L 23/53257

(57) ABSTRACT

A semiconductor device according to an. embodiment includes a gate electrode; a conductive layer; an insulating layer provided between the gate electrode and the conductive layer; and a contact plug that is surrounded by the insulating layer, connects the gate electrode and the conductive layer, and includes a first region and a second region, the second region being closer to the conductive layer than the first region, the width of the first region being greater than the width of the second region.

### CROSS-REFERENCE TO RELATED APPLICATION

This application is based upon and claims the benefit of priority from Japanese Patent Application No. 2018-055447, filed on Mar. 23, 2018, the entire contents of which are incorporated herein by reference.

### FIELD

Embodiments described. herein relate generally to a semiconductor device and a method for manufacturing the semiconductor device.

### BACKGROUND

In a case in which a contact plug for connecting a gate above electrode is formed, the contact hole is generally formed by anisotropic dry etching. However, problems, such as a reduction in the reliability of a gate oxide film and an increase in contact resistance, are likely to occur due to etching damage in dry etching. Therefore, itis preferable to reduce etching damage to the gate electrode.

### BRIEF DESCRIPTION OF THE DRAWINGS

FIG. 1 is a cross-sectional view schematically illustrating a semiconductor device according to a first embodiment;

FIG. 2 is a cross-sectional view schematically illustrating a method for manufacturing the semiconductor device according to the first. embodiment;

FIG. 3 is a cross-sectional view schematically illustrating the method. for manufacturing the semiconductor device according to the first embodiment;

FIG. 4 is a cross-sectional view schematically illustrating the method. for manufacturing the semiconductor device according to the first embodiment;

FIG. 5 is a cross-sectional view schematically illustrating the method for manufacturing the semiconductor device according to the first embodiment;

FIG. 6 is a cross-sectional view schematically illustrating the method for manufacturing the semiconductor device according to the first embodiment;

FIG. 7 is a cross-sectional view schematically illustrating a method for manufacturing a semiconductor device according to a comparative example;

FIG. 8 is a cross-sectional view schematically illustrating the method for manufacturing the semiconductor device according to the comparative example;

FIG. 9 is a cross-sectional view schematically illustrating the method for manufacturing the semiconductor device according to the comparative example;

FIG. 10 is a cross-sectional view schematically illustrating the method for manufacturing the semiconductor device according to the comparative example;

FIG. 11 is a cross-sectional view schematically illustrating a semiconductor device according to a second embodiment;

FIG. 12 is a cross-sectional view schematically illustrating a method for manufacturing the semiconductor device according to the second embodiment;

FIG. 13 is a cross-sectional view schematically illustrating the method for manufacturing the semiconductor device according to the second embodiment;

FIG. 14 is a cross-sectional view schematically

illustrating the method for manufacturing the semiconductor device according to the second embodiment;

FIG. 15 is a cross-sectional view schematically illustrating a semiconductor device according to a third embodiment;

FIG. 16 is a cross-sectional view schematically illustrating a method for manufacturing the semiconductor device according to the third embodiment;

FIG. 17 is a cross-sectional view schematically illustrating the method for manufacturing the semiconductor device according to the third embodiment;

FIG. 18 is a cross-sectional view schematically illustrating the method for manufacturing the semiconductor device according to the third embodiment; and

FIG. 19 is a cross-sectional view schematically illustrating the method for manufacturing the semiconductor device according to the third embodiment.

### DETAILED DESCRIPTION

A semiconductor device according to an aspect of the invention includes: a gate electrode; a conductive layer; an insulating layer provided between the gate electrode and the conductive layer; and a contact plug that is surrounded by the insulating layer, connects the gate electrode and the conductive layer, and includes a first region and a second region, the second region being closer to the conductive layer than the first region, a width of the first region being greater than a width of the second region.

In the specification, in some cases, the same or similar members are denoted by the same reference numerals and the description thereof will not be repeated.

In the specification, in some cases, in order to show the positional relationship between, for example, components, the upper direction in the drawings is described as an “upper side” and the lower direction in the drawings is described. as a “lower side”. In the specification, the terms “upper side” and “lower side” do not necessarily indicate the relationship with the direction of gravity.

### First Embodiment

A semiconductor device according to a first embodiment includes: a gate electrode; a conductive layer; an insulating layer provided between the gate electrode and the conductive layer; and a contact plug that is surrounded by the insulating layer, connects the gate electrode and the conductive layer, and includes a first region and a second region, the second region being closer to the conductive layer than the first region, a width of the first region being greater than a width of the second region. The insulating layer includes: a first insulating film provided on the gate electrode; a second insulating film that is provided on the first insulating film and is made of a material different from a material forming the first insulating film; and a third insulating film that is provided on the second insulating film and is made of a material different from the material forming the second insulating film. The first region is surrounded by the first insulating film and the second region is surrounded by the second insulating film.

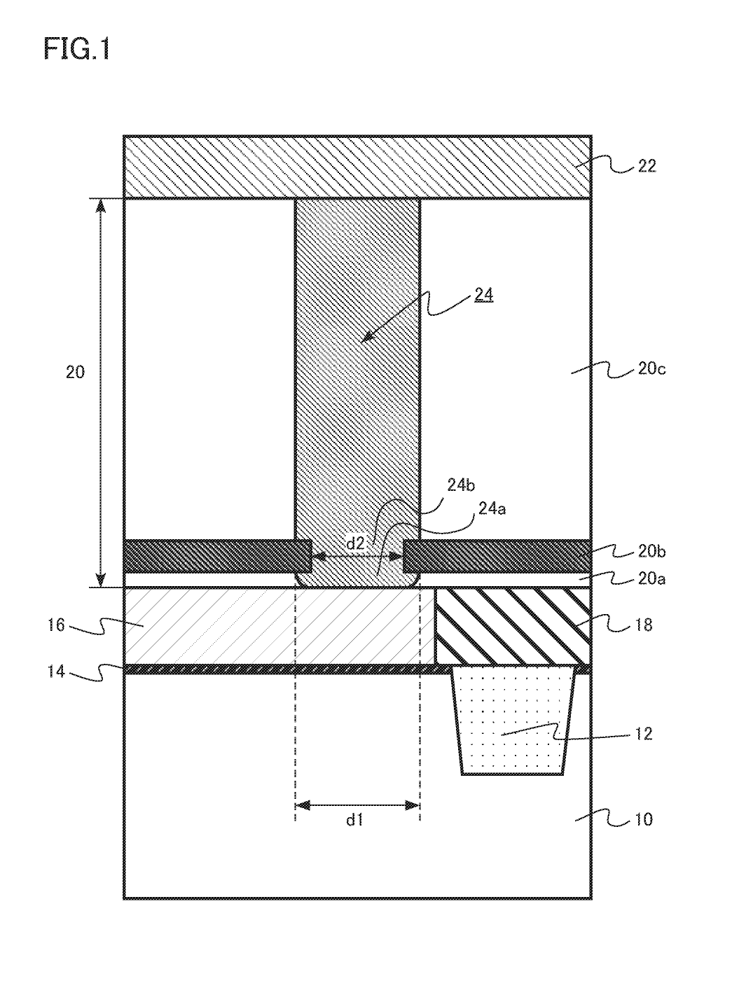

FIG. 1 is a cross-sectional view schematically illustrating the semiconductor device according to the first embodiment.

The semiconductor device according to the first embodiment includes a silicon substrate 10, an element isolation insulating film. 12, a gate insulating film 14, a gate electrode 16, an inter-gate electrode insulating layer 18, an interlayer insulating layer 20 (insulating layer), a wire 22 (conductive layer), and a contact plug 24. The interlayer insulating layer 20 includes a first silicon oxide film 20a (first insulating film), a silicon nitride film 20b (second insulating film), and a second silicon oxide film 20c (third insulating film). The contact plug 24 includes a first region 24a and a second region 24b.

The silicon substrate 10 is a single-crystal silicon substrate. For example, a source impurity region (not illustrated) or a drain impurity region (not illustrated) is formed in the silicon substrate 10. For example, a transistor is formed by the gate electrode 16, the source impurity region, and the drain impurity region.

The element isolation insulating film 12 is provided in a trench provided in the silicon substrate 10. The element isolation insulating film 12 is made of, for example, silicon oxide. A shallow trench isolation (STI) structure is formed by the element isolation insulating film 12 in the trench.

The gate insulating film 14 is provided between the gate electrode 16 and the silicon substrate 10. The gate insulating film 14 is made of, for example, silicon oxide.

The gate electrode 16 is provided on the gate insulating film 14 and the element isolation insulating film 12. The gate electrode 16 is made of a semiconductor, metal, or a metal compound.

For example, the inter-gate electrode insulating layer 18 is provided between the gate electrode 16 and an adjacent gate electrode 16 (not illustrated). The inter-gate electrode insulating layer 18 is made of, for example, silicon oxide.

The wire 22 is an example of a conductive layer. The wire 22 is made of, for example, metal.

The interlayer insulating layer 20 is provided between the gate electrode 16 and the wire 22. The interlayer insulating layer 20 is an example of an insulating layer.

The interlayer insulating layer 20 includes the first silicon oxide film 20a, the silicon nitride film 20b, and the second silicon oxide film 20c. The first silicon oxide film 20a is an example of a first insulating film. The silicon nitride film 20b is an example of a second insulating film. The second silicon oxide film 20c is an example of a third insulating film.

The first silicon oxide film 20a is provided on the gate electrode 16. The silicon nitride film 20b is provided on the first silicon oxide film 20a. The second silicon oxide film 20c is provided on the silicon nitride film 20b. The material forming the silicon nitride film 20b is different from the material forming the first silicon oxide film 20a. The material forming the second silicon oxide film 20c is different from the material forming the silicon nitride film 20b.

The silicon nitride film 20b functions as an etching stopper in a case in which contact hole etching for forming the contact plug 24 is performed.

The contact plug 24 is surrounded by the interlayer insulating layer 20. The contact plug 24 is provided so as to pass through the interlayer insulating layer 20. The contact plug 24 connects the gate electrode 16 and the wire 22.

The contact plug 24 includes the first region 24a and the second region 24b. The second region 24b is closer to the wire 22 than the first region 24a. The first region 24a is closer to the gate electrode 16 than the second region 24b.

The first region 24a contacts the gate electrode 16. The first region 24a is provided immediately above the gate electrode 16. The first region 24a is surrounded by the first silicon oxide film 20a. A portion of the first region 24a is interposed between the gate electrode 16 and the con nitride film 20b.

The second region 24b is surrounded by the silicon nitride film 20b.

The width (d1 in FIG. 1) of the first region 24a is greater than the width (d2 in FIG. 1) of the second region 24b. The contact plug 24 is isotropically widened in the vicinity of the gate electrode 16.

The contact plug 24 is made of metal. The contact plug 24 is made of, for example, titanium, titanium nitride, or tungsten. The contact plug 24 may include a barrier metal film.

Next, a method for manufacturing the semiconductor device according to the first embodiment will be described.

The method for manufacturing the semiconductor device according to the first embodiment includes: forming a gate electrode; forming a first insulating film on the gate electrode; forming a second insulating film on the first insulating film, a material forming the second insulating film being different from a material forming the first insulating film; forming a third insulating film on the second insulating film, a material forming the third insulating film being different from the material forming the second insulating film; etching the third insulating film using anisotropic dry etching to form a contact hole, the second insulating film being exposed at a bottom of the contact hole; removing the second insulating film at the bottom of the contact hole; and removing the first insulating film at the bottom of the contact hole using wet etching such that the gate electrode is exposed.

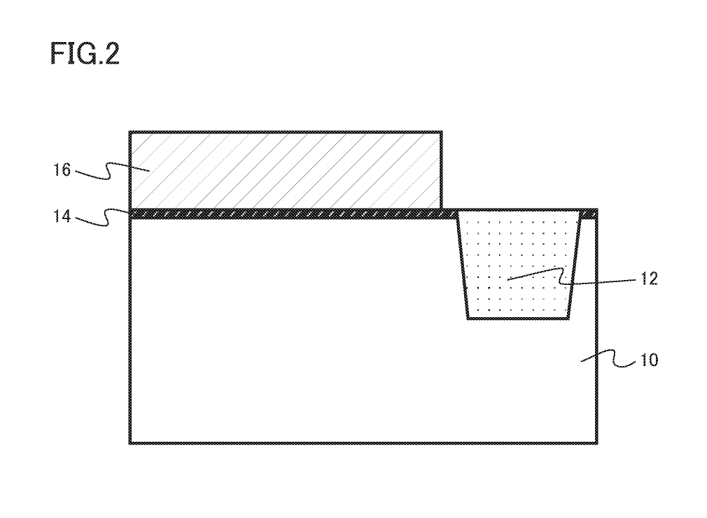

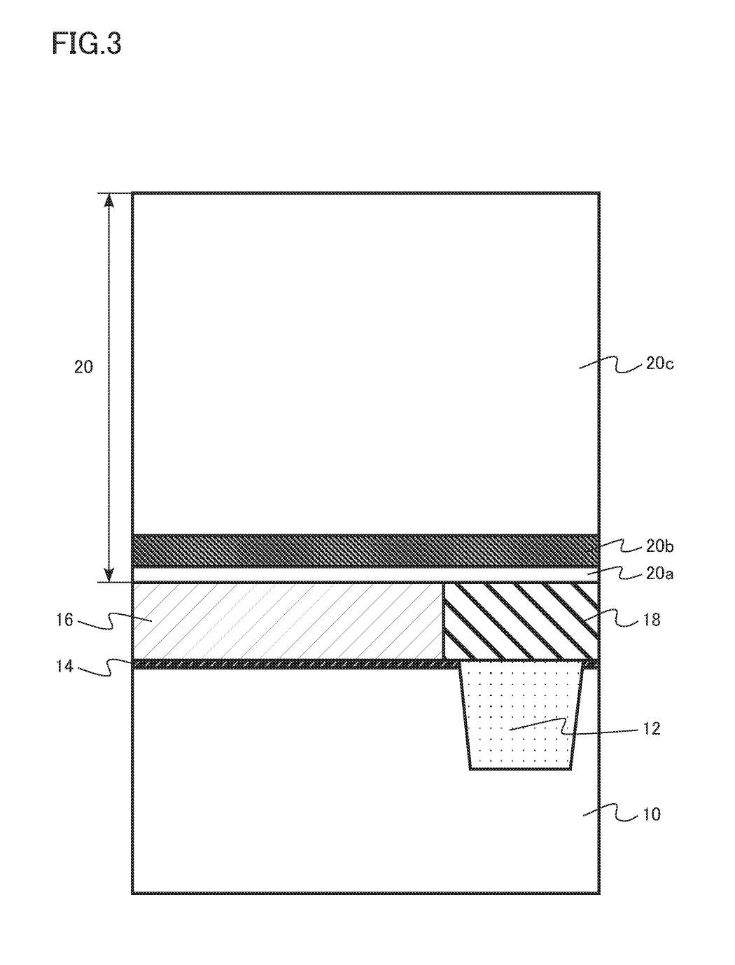

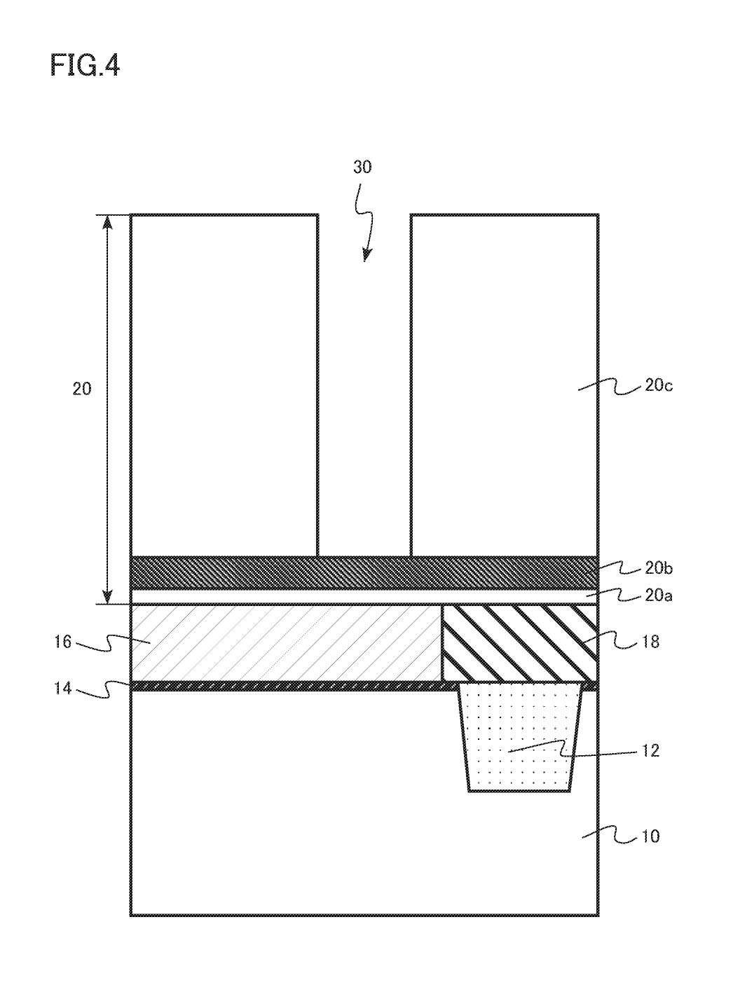

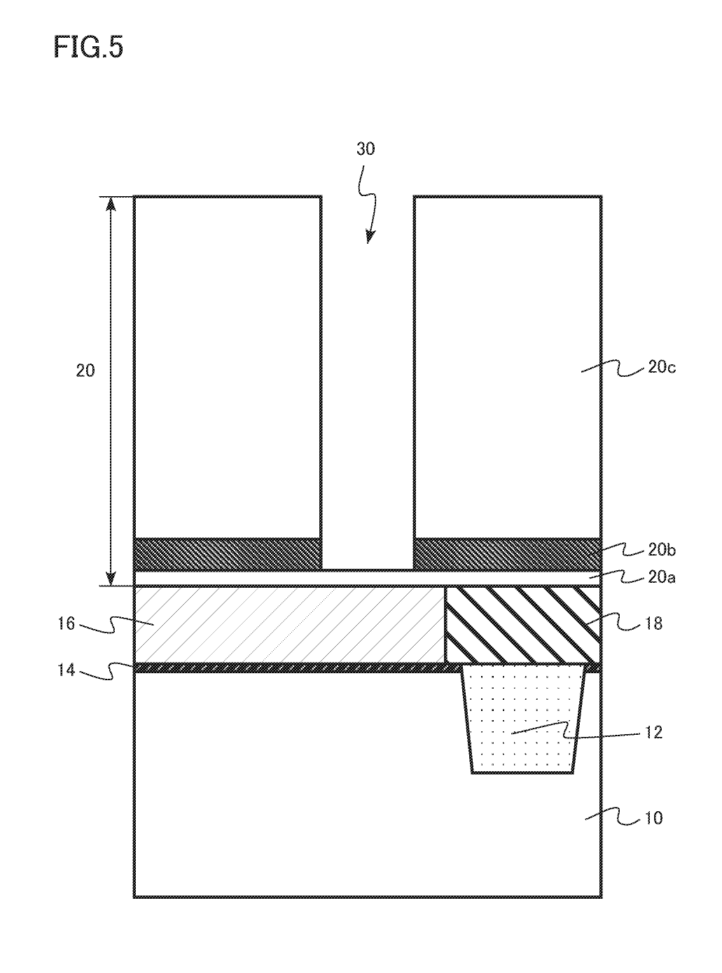

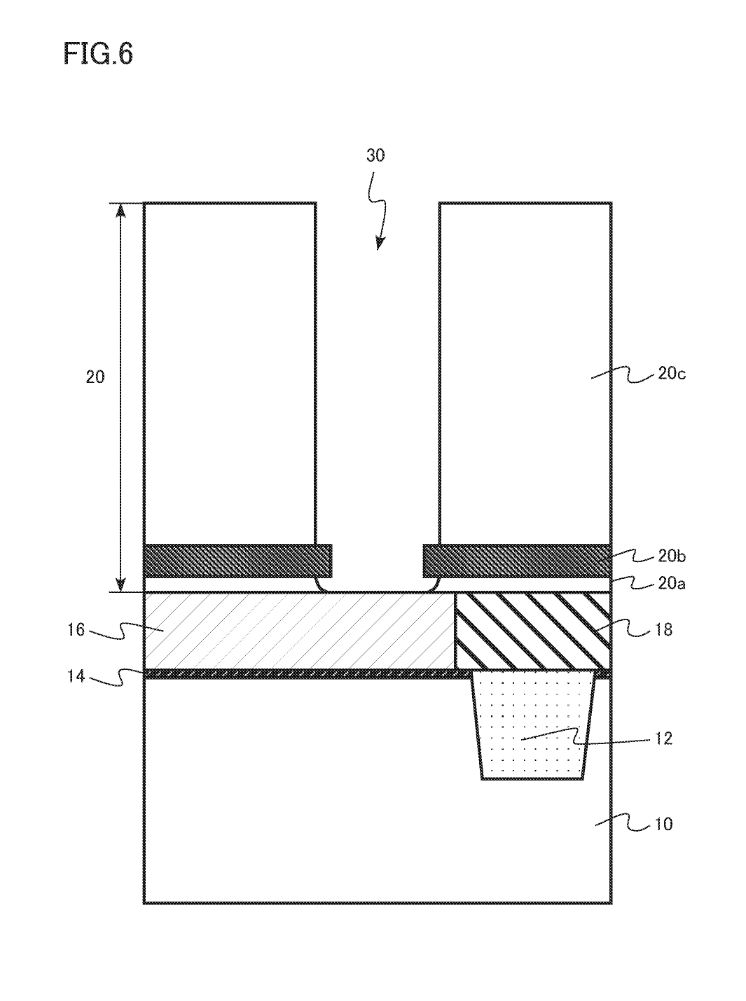

FIG. 2, FIG. 3, FIG. 4, FIG. 5, and FIG. 6 are cross-sectional views schematically illustrating the method for manufacturing the semiconductor device according to the first embodiment.

First, the element isolation insulating film 12, the gate insulating film 14, and the gate electrode 16 are formed on the silicon substrate 10 by a known method (FIG. 2). Then, the inter-gate electrode insulating layer 18 is formed.

Then, the first silicon oxide film 20a is formed on the gate electrode 16, the silicon nitride film 20b is formed on the first silicon oxide film 20a, and the second silicon oxide film 20c is formed on the silicon nitride film 20b (FIG. 3). The first silicon oxide film 20a, the silicon nitride film 20b, and the second silicon oxide film 20c are formed by, for example, a chemical vapor deposition (CVD) method.

Then, the second silicon oxide film 20c is etched by anisotropic dry etching to form a contact hole 30 (FIG. 4). The etching rate of the silicon nitride film 20b when the second silicon oxide film 20c is etched is lower than. the etching rate of the second silicon oxide film 20c. Therefore, when. the contact hole 30 is formed, the silicon nitride film 20b functions as an etching stopper. The silicon nitride film 20b is exposed at the bottom of the contact hole 30. The anisotropic dry etching is, for example, reactive ion etching (RIE).

Then, the silicon nitride film 20b at the bottom of the contact hole 30 is removed by anisotropic dry etching (FIG. 5). The silicon nitride film 20b may be removed by wet etching.

Then, the first silicon oxide film 20a at the bottom of the contact hole 30 is removed by wet etching (FIG. 6). The surface of the gate electrode 16 is exposed by the removal of the first silicon oxide film 20a.

The wet etching is isotropic etching. Therefore, the first silicon oxide film 20a is also etched in the lateral direction and the bottom of the contact hole 30 is isotropically widened. The second silicon oxide film 20c is also etched in the lateral direction.

Hydrofluoric-acid-based chemicals are used for the wet etching. For example, buffered hydrofluoric acid is used as the chemical. The buffered hydrofluoric acid is a mixed solution of hydrofluoric acid and ammonium fluoride.

Then, the contact plug 24 and the wire 22 are formed by a known method.

The semiconductor device illustrated in FIG. 1 in which the contact plug 24 is formed on the gate electrode 16 is manufactured by the above-mentioned manufacturing method.

Then, the function and effect of the first embodiment will be described.

In a case in which the contact plug for connecting the wire provided in the layer above the gate electrode and the gate electrode is formed, the contact hole is formed by anisotropic dry etching. However, problems, such as a reduction in the reliability of the gate oxide film and an increase in contact resistance, are likely to occur due to etching damage in anisotropic dry etching. Therefore, it is preferable to reduce etching damage to the gate electrode.

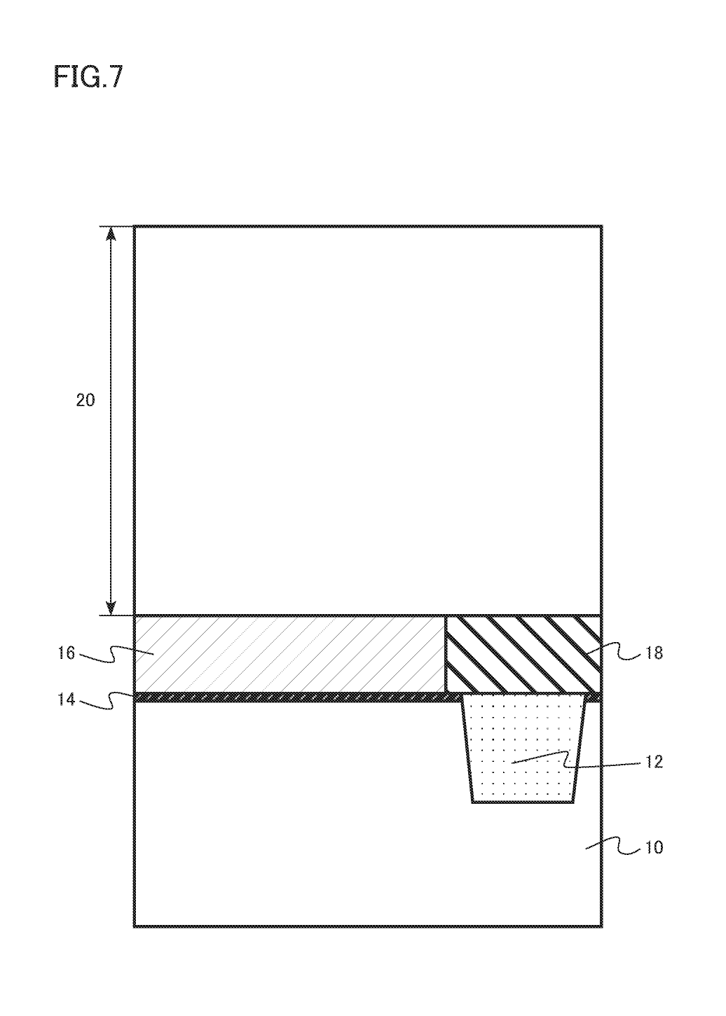

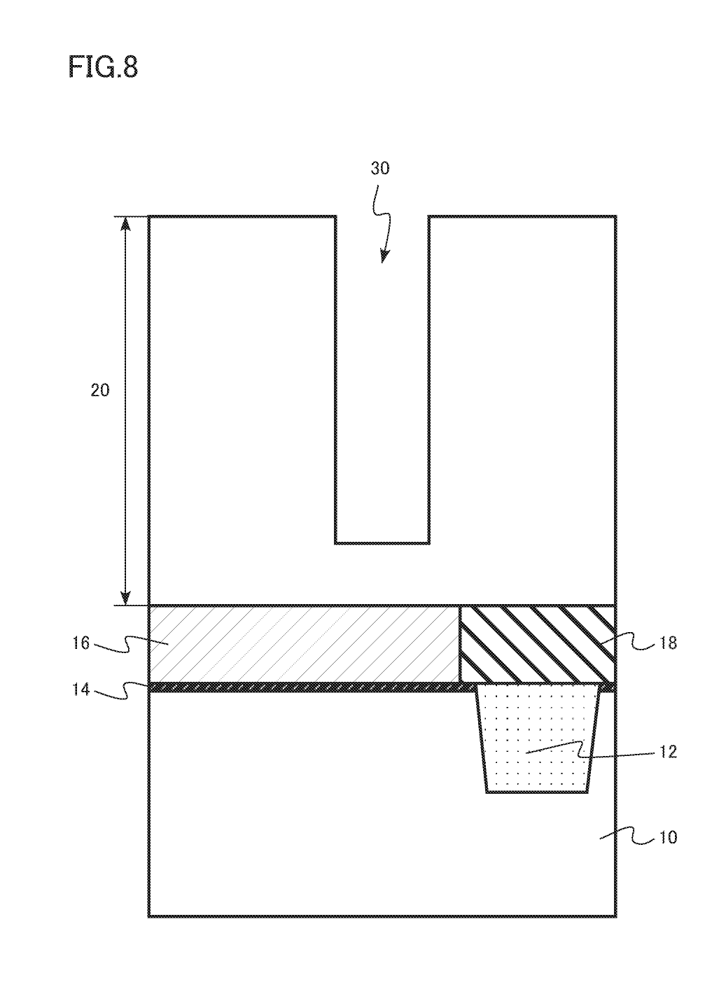

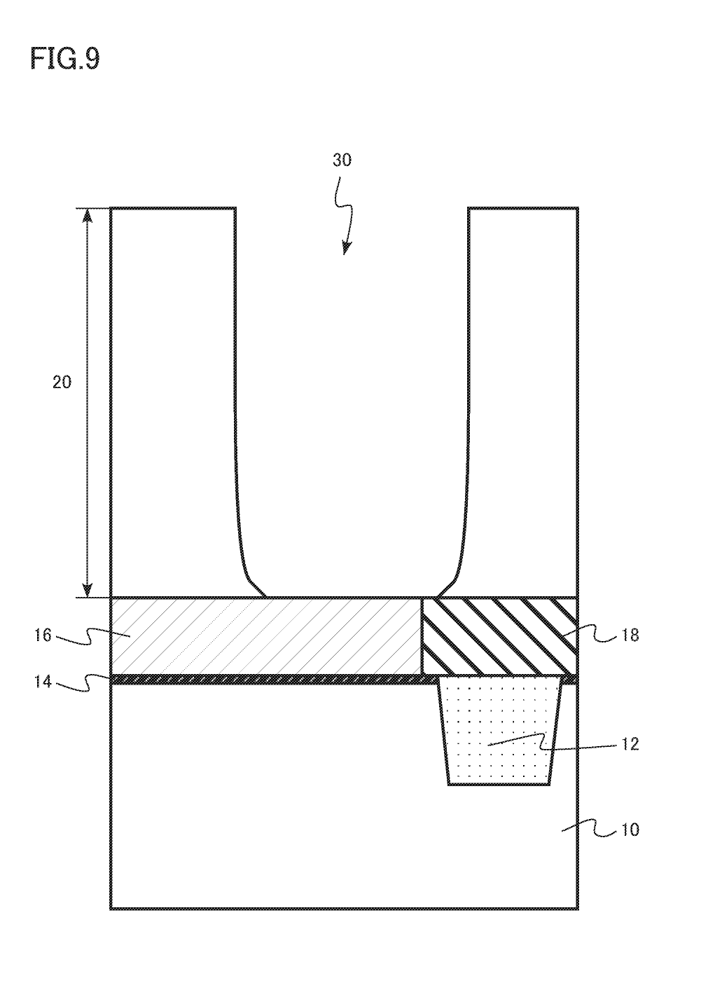

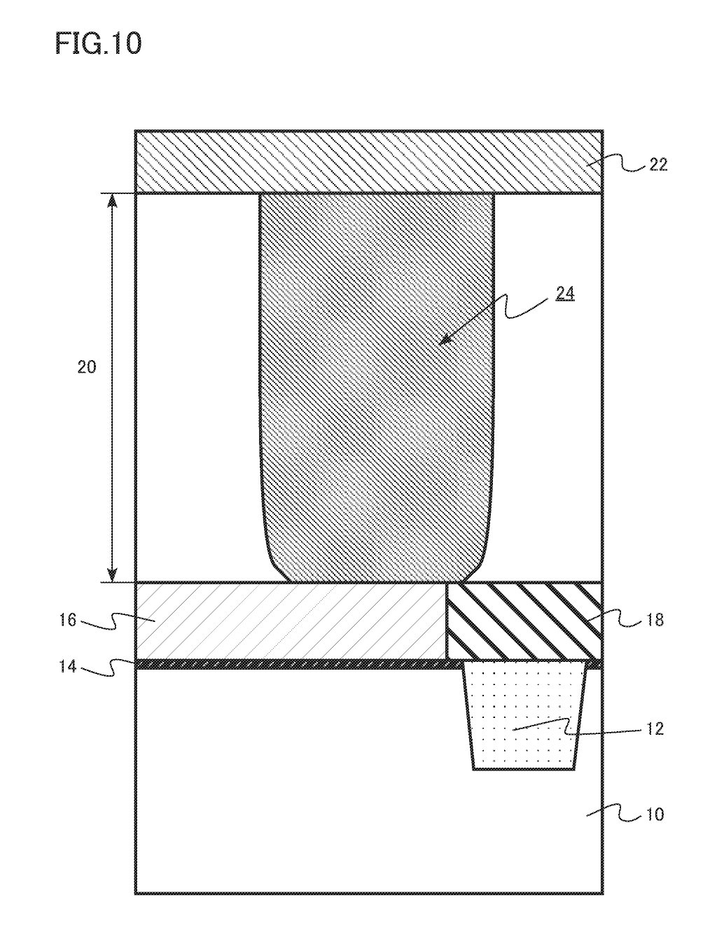

FIG. 7, FIG. 8, FIG. 9, and FIG. 10 are cross-sectional views schematically illustrating a semiconductor device manufacturing method according to a comparative example.

The semiconductor device manufacturing method according to the comparative example differs from the semiconductor device manufacturing method according to the first embodiment in that the silicon nitride film 20b functioning as an etching stopper is not formed. Hereinafter, the description of a portion of the same content as that in the manufacturing method according to the first embodiment will not be repeated.

First, the element isolation insulating film 12, the gate insulating film 14, and the gate electrode 16 are formed on the silicon substrate 10 by a known method. Then, the inter-gate electrode insulating layer 18 is formed.

Then, the interlayer insulating layer 20 is formed on the gate electrode 16. The interlayer insulating layer 20 is made of, for example, silicon oxide (FIG. 7).

Then, the interlayer insulating layer 20 is etched by anisotropic dry etching to form a contact hole 30 (FIG. 8). At that time, etching is stopped in the middle of the interlayer insulating layer 20. The interlayer insulating layer 20 is exposed at the bottom of the contact hole 30.

Then, the interlayer insulating layer 20 at the bottom of the contact hole 30 is removed by wet etching (FIG. 9). The surface of the gate electrode 16 is exposed by the removal of the interlayer insulating layer 20.

The wet etching is isotropic etching. Therefore, the interlayer insulating layer 20 is also etched in the lateral direction and the bottom and side of the contact hole 30 are isotropically widened.

Then, the contact plug 24 and the wire 22 are formed by a known method (FIG. 10).

In the manufacturing method according to the comparative example, anisotropic dry etching is stopped before the contact hole 30 reaches the gate electrode 16. Therefore, the gate electrode 16 is not exposed to anisotropic dry etching. As a result, it is possible to reduce etching damage to the gate electrode 16.

However, since the interlayer insulating layer 20 that remains at the bottom of the contact hole 30 is thick, the diameter of the contact hole 30 is significantly increased by isotropic wet etching. Therefore, the width of the contact plug 24 increases significantly as illustrated in FIG. 10. As a result, for example, there is a concern that a short circuit will occur between adjacent contact plugs 24 or between adjacent wires.

In the manufacturing method according to the first embodiment, the gate electrode 16 is not exposed to anisotropic dry etching as in the manufacturing method according to the comparative example. Therefore, it is possible to reduce etching damage to the gate electrode 16.

In addition, in the manufacturing method according to the first embodiment, the silicon nitride film 20b functioning as an etching stopper is formed. Only the thin first silicon oxide film 20a is etched by wet etching. Therefore, an increase in the diameter of the contact hole 30 caused by isotropic wet etching is prevented. As a result, it is possible to reduce the width of the contact plug 24.

As described above, according to the first embodiment, it is possible to achieve a semiconductor device that reduces etching damage to a gate electrode and a method for manufacturing the semiconductor device.

### Second Embodiment

In a semiconductor device according to a second embodiment, an insulating layer includes a first insulating film provided on a gate electrode and a second insulating film that is provided on the first insulating film and is made of a material different from a material forming the first insulating film, a first region is surrounded by the first insulating film, and a second region is surrounded by the second insulating film. The semiconductor device according to the second embodiment differs from the semiconductor device according to the first embodiment in that it does not include the third insulating film. Hereinafter, the description of a portion of the same content as that in the first embodiment will not be repeated.

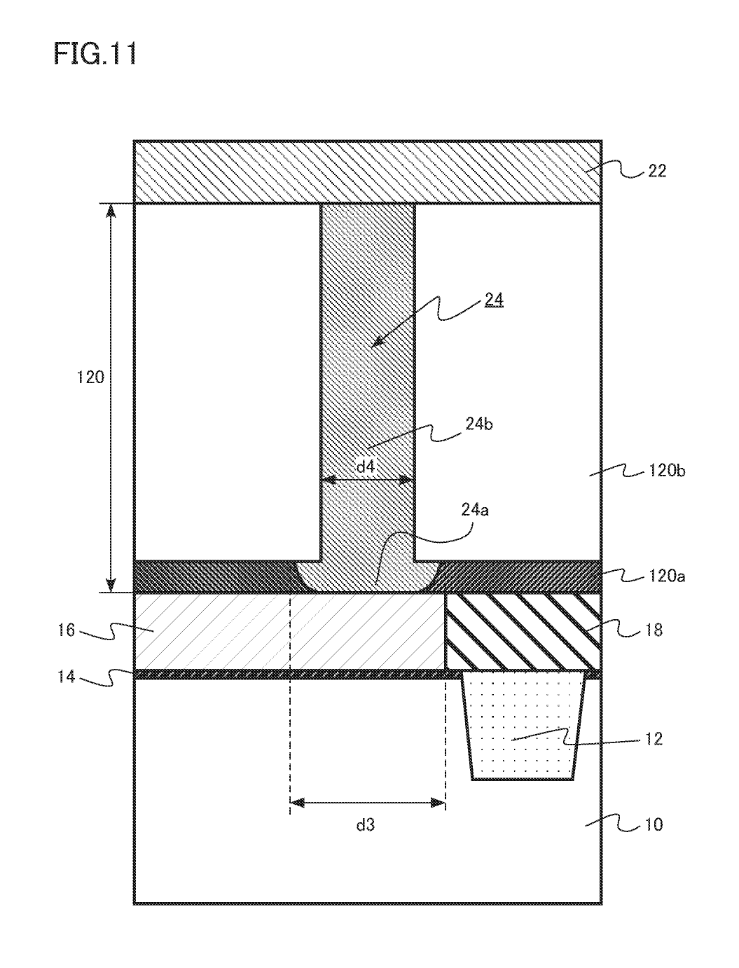

FIG. 11 is a cross-sectional view schematically illustrating the semiconductor device according to the second embodiment.

The semiconductor device according to the second embodiment includes a silicon substrate 10, an element isolation insulating film 12, a gate insulating film 14, a gate electrode 16, an inter-gate electrode insulating layer 18, an interlayer insulating layer 120 (insulating layer), a wire 22 (conductive layer), and a contact plug 24. The interlayer insulating layer 120 includes a silicon nitride film 120a (first insulating film) and a silicon oxide film 120b (second insulating film). The contact plug 24 includes a first region 21a and a second region 24b.

The silicon substrate 10 is a single-crystal silicon substrate. For example, a source impurity region (not illustrated) or a drain impurity region (not illustrated) is formed in the silicon substrate 10. For example, a transistor is formed by the gate electrode 16, the source impurity region, and the drain impurity region.

The element isolation insulating film 12 is provided in a trench provided in the silicon substrate 10. The element isolation insulating film 12 is made of, for example, silicon oxide.

The gate insulating film 14 is provided between the gate electrode 16 and the silicon substrate 10. The gate insulating film 14 is made of, for example, silicon oxide.

The gate electrode 16 is provided on the gate insulating film 14 and the element isolation insulating film 12. The gate electrode 16 is made of a semiconductor, metal, or a metal compound.

For example, the inter-gate electrode insulating layer 18 is provided between the gate electrode 16 and a gate electrode 16 (not illustrated). The inter-gate electrode insulating layer 18 is made of, for example, silicon oxide,

The wire 22 is an example of a conductive layer. The wire 22 is made of, for example, metal.

The interlayer insulating layer 120 is provided between the gate electrode 16 and the wire 22. The interlayer insulating layer 120 is an example of an insulating layer.

The interlayer insulating layer 120 includes the silicon nitride film 120a and the silicon oxide film 120b. The silicon nitride film 120a is arm example of a first insulating film. The silicon oxide film 120b is an example of a second insulating film.

The silicon nitride film 120a is provided on the gate electrode 16. The silicon oxide 120b is provided on the silicon nitride film 120a. The material forming the silicon oxide film 120b is different from the material forming the silicon nitride film 120a.

The silicon nitride film 120a functions as an etching stopper when a contact hole etching for forming the contact plug 24 is performed.

The contact plug 24 is surrounded by the interlayer insulating layer 120. The contact plug 24 is provided so as to pass through the interlayer insulating layer 120. The contact plug 24 connects the gate electrode 16 and the wire 22.

The contact plug 24 includes the first region 24a and the second region 24b. The second region 24b is closer to the wire 22 than the first region 24a. The first region 24a is closer to the gate electrode 16 than the second region 24b.

The first region 24a contacts the gate electrode 16. The first region 24a is provided immediately above the gate electrode 16. The first region 24a is surrounded by the silicon nitride film 120a. A portion of the first region 24a is interposed between the gate electrode 16 and the silicon oxide film 120b.

The second region 24b is surrounded by the silicon oxide film 120b.

The width (d3 in FIG. 11) of the first region 24a is greater than the width (d4 in FIG. 11) of the second region 24b. The contact plug 24 is isotropically widened in the vicinity of the gate electrode 16.

The contact plug 24 is made of metal. The contact plug 24 is made of, for example, titanium, titanium nitride, or tungsten. The contact plug 24 may include a barrier metal film.

Next, a method for manufacturing the semiconductor device according to the second embodiment will be described.

The method for manufacturing the semiconductor device according to the second embodiment includes: forming a gate electrode; forming a first insulating film on the gate electrode; forming a second insulating film on the first insulating film, a material forming the second insulating film being different from a material forming the first insulating film; etching the second insulating film using anisotropic dry etching to form a contact hole, the first insulating film being exposed at a bottom of the contact hole; and removing the first insulating film at the bottom of the contact hole using wet etching such that the gate electrode is exposed.

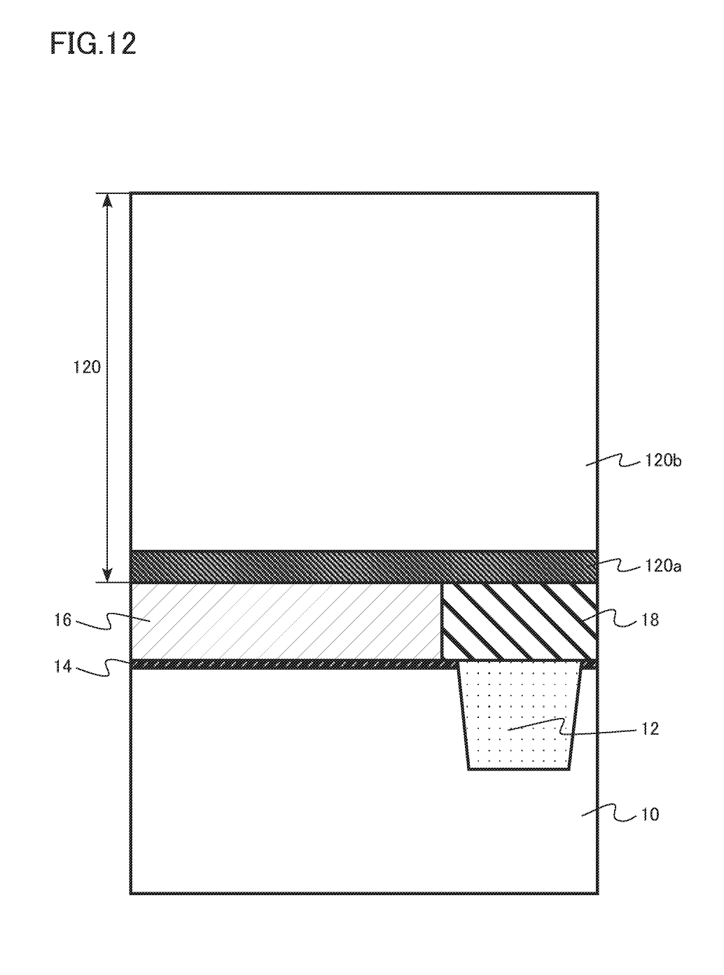

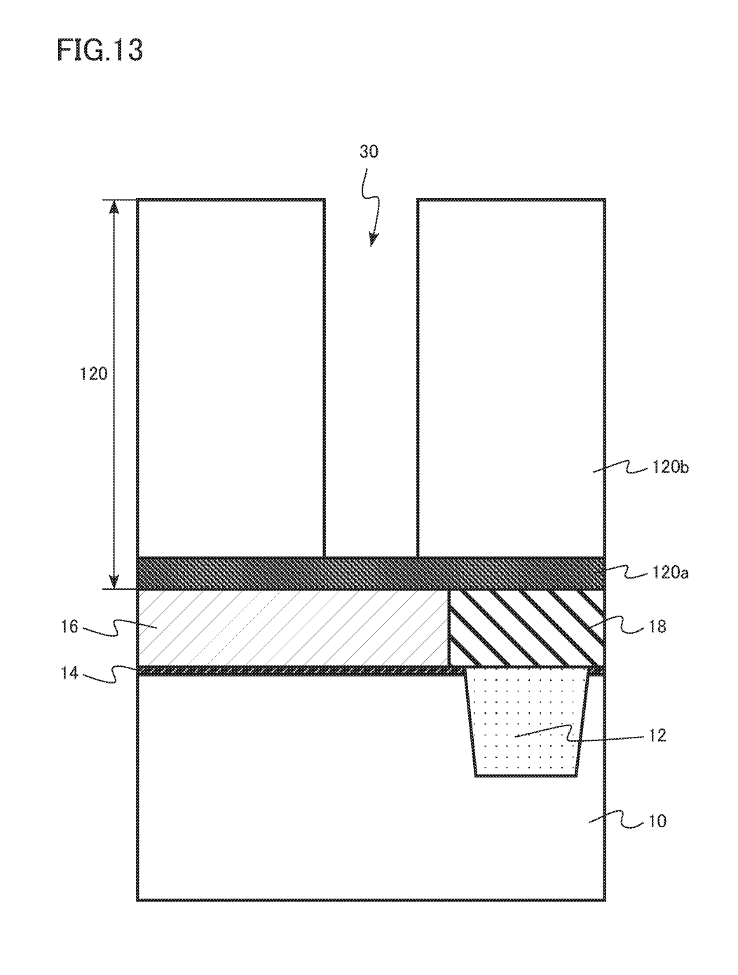

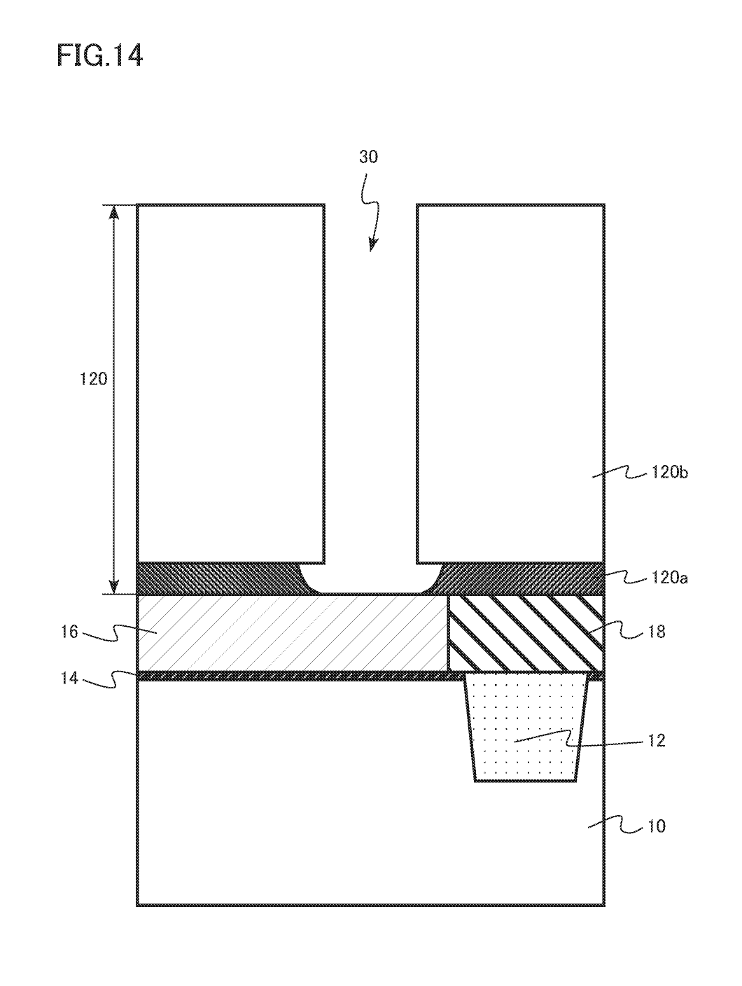

FIG. 12, FIG. 13, and FIG. 14 are cross-sectional views schematically illustrating the method for manufacturing the semiconductor device according to the second embodiment.

First, the element isolation insulating film 12, the gate insulating film 14, and the gate electrode 16 are formed on the silicon substrate 10 by a known method. Then, the inter-gate electrode insulating layer 18 is formed.

Then, the silicon nitride film 120a is formed on the gate electrode 16 and the silicon oxide film 120b is formed on the silicon nitride film 120a (FIG. 12).

Then, the silicon oxide film 120b is etched by anisotropic dry etching to form the contact hole 30 (FIG. 13). When the contact hole 30 is formed, the silicon nitride film 120a functions as an etching stopper. The silicon nitride film 120a is exposed at the bottom of the contact hole 30. The anisotropic dry etching is, for example, RIE.

Then, the silicon nitride film 120a at the bottom of the contact hole 30 is removed by wet etching (FIG. 14). The surface of the gate electrode 16 is exposed by the removal of the silicon nitride film 120a.

For example, the wet etching is performed using thermal phosphoric acid. The wet etching is isotropic etching. Therefore, the silicon nitride film 120a is also etched in the lateral direction and the bottom of the contact hole 30 is isotropically widened. The silicon oxide film 120b is not etched in the lateral direction since it has a very low etching rate for thermal phosphoric acid.

Then, the contact plug 24 and the wire 22 are formed by a known method.

The semiconductor device illustrated in FIG. 11 in which the contact plug 24 is provided on the gate electrode 16 is manufactured by the above-mentioned manufacturing method.

In the manufacturing method according to the second embodiment, the gate electrode 16 is not exposed to anisotropic dry etching as in the manufacturing method according to the first embodiment. Therefore, it is possible to reduce etching damage to the gate electrode 16.

In addition, in the manufacturing method according to the second embodiment, the silicon nitride film 120a functioning as an etching stopper is formed immediately above the gate electrode 16. Only the silicon nitride film 120a is etched by wet etching. When wet etching is performed for the silicon nitride film 120a, the silicon oxide film 120b is hardly etched and the width of a portion of the contact hole 30 other than the bottom does not increase. Therefore, the width of the contact plug 24 can be less than that in the first embodiment. As a result, for example, a short circuit between adjacent contact plugs 24 or a short circuit between adjacent wires is prevented.

As described above, according to the second embodiment, it is possible to achieve a semiconductor device that reduces etching damage to a gate electrode and a method for manufacturing the semiconductor device. In addition, the width of the contact plug 24 can be less than that in the first embodiment.

### Third Embodiment

A semiconductor device according to a third embodiment differs from the semiconductor device according to the first embodiment in that a sidewall insulating film is provided between the second region of the contact plug and the insulating layer. Hereinafter, the description of a portion of the same content as that in the first embodiment will not be repeated.

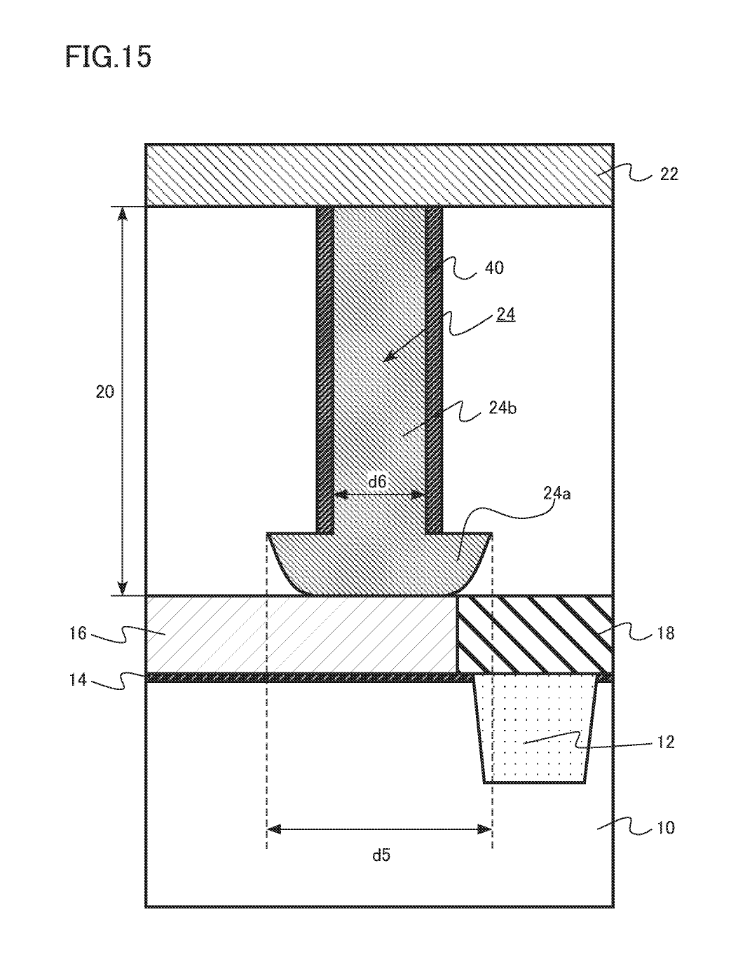

FIG. 15 is a cross-sectional view schematically illustrating the semiconductor device according to the third embodiment.

The semiconductor device according to the third embodiment includes a silicon substrate 10, an element isolation insulating film 12, a gate insulating film 14, a gate electrode 16, an inter-gate electrode insulating layer 18, an interlayer insulating layer 12 (insulating layer), a wire 22 (conductive layer), a contact plug 24, and a sidewall insulating film 40. The contact plug 24 includes a first region. 24a and a second region 24b.

The silicon substrate 10 is a single-crystal silicon substrate. For example, a source impurity region (not illustrated) or a drain impurity region (not illustrated) is formed in the silicon substrate 10. For example, a transistor is formed by the gate electrode 16, the source impurity region, and the drain impurity region.

The element isolation insulating film 12 is provided in a trench provided in the silicon substrate 10. The element isolation insulating film 12 is made of, for example, silicon oxide.

The gate insulating film 14 is provided between the gate electrode 16 and the silicon substrate 10. The gate insulating film 14 is made of, for example, silicon oxide.

The gate electrode 16 is provided on the gate insulating film 14 and the element isolation insulating film 12. The gate electrode 16 is made of a semiconductor, metal, or a metal compound.

The inter-gate electrode insulating layer 18 is provided between the gate electrode 16 and a gate electrode (not illustrated). The inter-gate electrode insulating layer 18 is made of, for example, silicon oxide.

The wire 22 is an example of a conductive layer. The wire 22 is made of, for example, metal.

The interlayer insulating layer 20 is provided between the gate electrode 16 and the wire 22. The interlayer insulating layer 20 is an example of an insulating layer. The interlayer insulating layer 20 is made of, for example, silicon oxide.

The sidewall insulating film 40 is provided between the second region 24b of the contact plug 24 and the interlayer insulating layer 20. The sidewall insulating film 40 is made of, for example, silicon nitride.

The contact plug 24 is surrounded by the interlayer insulating layer 20. The contact plug 24 is provided so as to pass through the interlayer insulating layer 12. The contact plug 24 connects the gate electrode 16 and the wire 22.

The contact plug 24 includes the first region 24a and the second region 24b. The second region 24b is closer to the wire 22 than the first region 24a. The first region 24a is closer to the gate electrode 16 than the second region 24b.

The first region 24a. contacts the gate electrode 16. A portion of the first region 24a is interposed between the gate electrode 16 and the sidewall insulating film 40.

The second region 24b is surrounded by the sidewall insulating film 40.

The width (d5 in FIG. 15) of the first region 24a is greater than the width (d6 in FIG. 15) of the second region 24b. The contact plug 24 is isotropically widened in the vicinity of the gate electrode 16.

The contact plug 24 is made of metal. The contact plug 24 is made of, for example, titanium, titanium nitride, or tungsten. The contact plug 24 may include a barrier metal film.

Next, a method for manufacturing the semiconductor device according to the third embodiment will be described.

The method for manufacturing the semiconductor device according to the third embodiment includes: forming a gate electrode; forming an insulating layer on the gate electrode; etching the insulating layer using anisotropic dry etching to form a contact hole such that a portion of the insulating layer remains between the contact hole and the gate electrode; forming sidewall insulating film on a side surface of the contact hole; and removing a portion of the insulating layer at a bottom of the contact hole using wet etching such that the gate electrode is exposed.

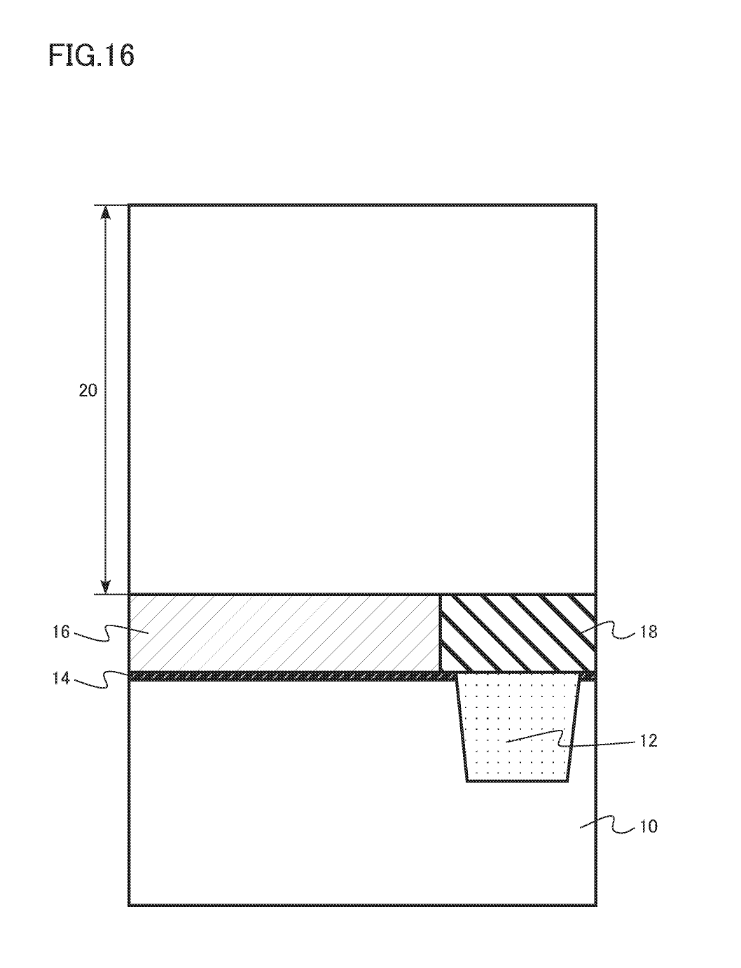

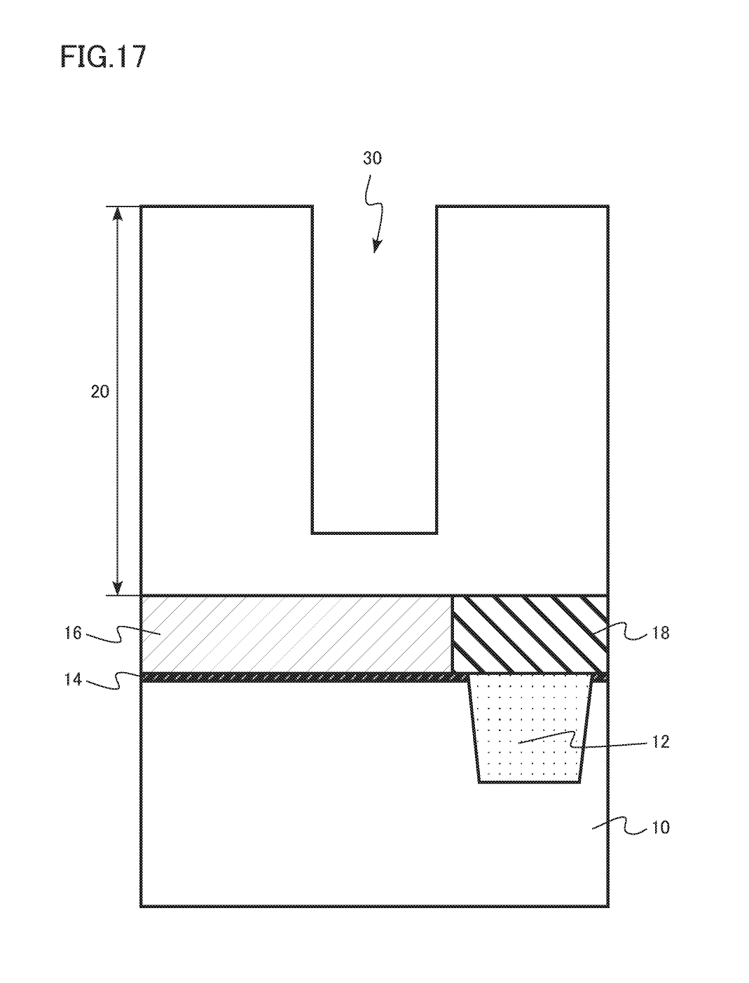

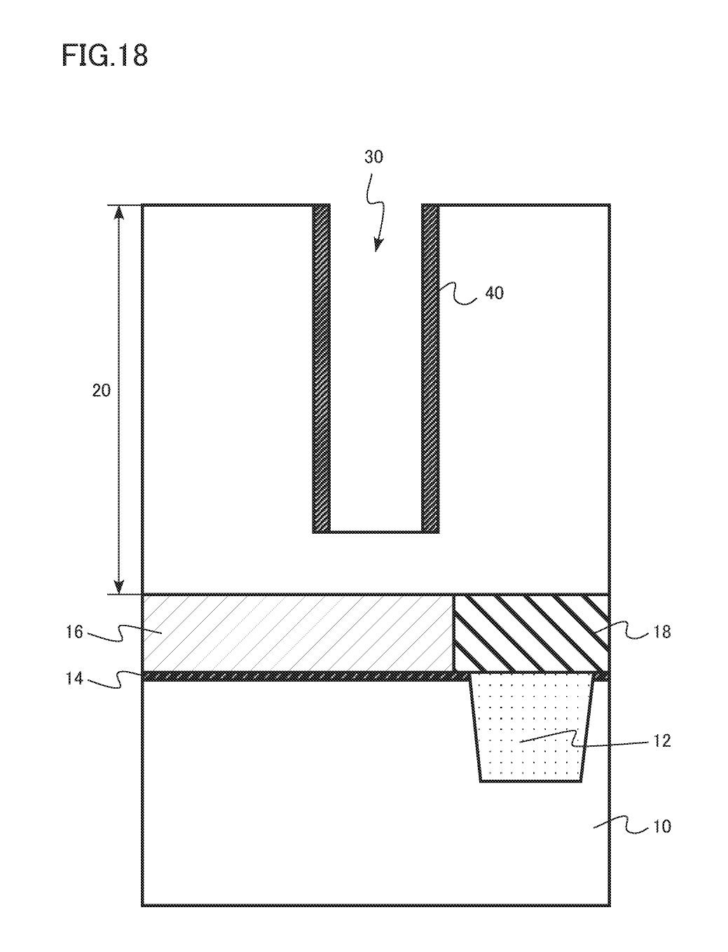

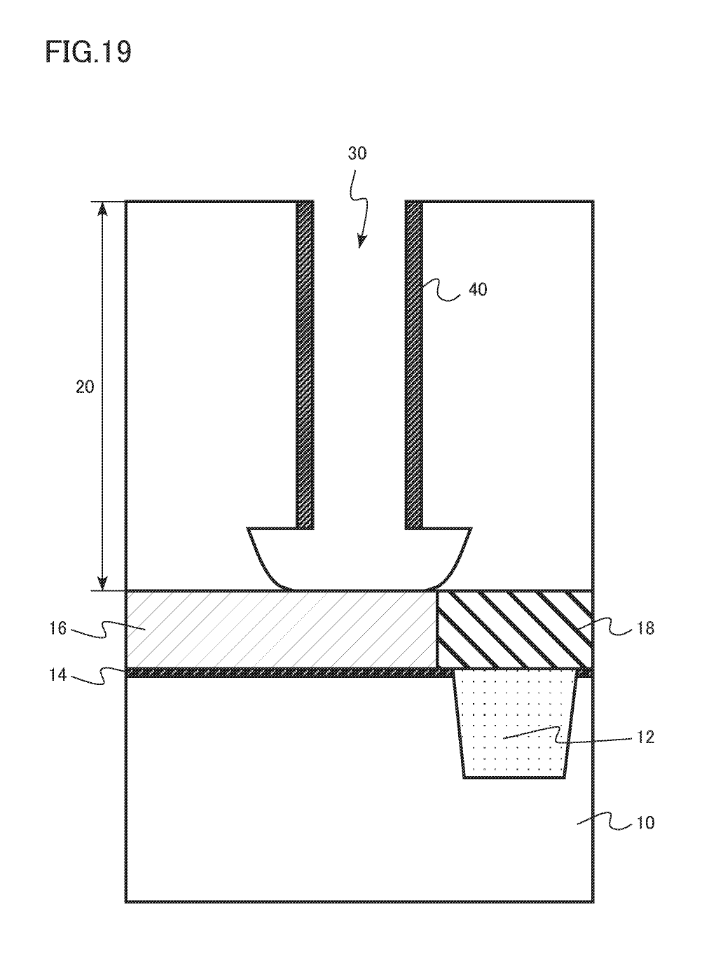

FIG. 16, FIG. 17, FIG. 18, and FIG. 19 are cross-sectional views schematically illustrating the method for manufacturing the semiconductor device according to the third embodiment.

First, the element isolation insulating film 12, the gate insulating film 14, and the gate electrode 16 are formed on the silicon substrate 10 by a known method. Then, the inter-gate electrode insulating layer 18 is formed.

Then, the interlayer insulating layer 20 is formed on the gate electrode 16. The interlayer insulating layer 20 is made of, for example, silicon oxide (FIG. 16).

Then, the interlayer insulating layer 20 is etched by anisotropic dry etching to form the contact hole 30 (FIG. 17). At that time, a portion of the interlayer insulating layer 20 remains between the gate electrode 16 and the contact hole 30. In other words, the etching of the contact hole 30 is stopped in the middle of the interlayer insulating layer 20. The interlayer insulating layer 20 is exposed at the bottom of the contact hole 30.

Then, the sidewall insulating film 40 is formed on the side surface of the contact hole 30 (FIG. 18). The sidewall insulating film 40 is made of silicon nitride. The sidewall insulating film 40 is formed by, for example, the deposition of a silicon nitride film by a CVD method and the selective etching of the silicon nitride film at the bottom of the contact hole 30 by an RIE method.

Then, the interlayer insulating layer 20 at the bottom of the contact hole 30 is removed by wet etching (FIG. 19). The surface of the gate electrode 16 is exposed by the removal of the interlayer insulating layer 20.

Hydrofluoric-acid-based chemicals are used for the wet etching. For example, buffered hydrofluoric acid is used as the chemical. The buffered hydrofluoric acid is a mixed solution of hydrofluoric acid and ammonium fluoride.

The wet etching is isotropic etching. Therefore, the interlayer insulating layer 20 is also etched in the lateral direction and the bottom of the contact hole 30 is isotropically widened. In contrast, the interlayer insulating layer 20 corresponding to the side surface of the contact hole 30 covered by the sidewall insulating film 40 is not etched and the contact hole 30 is not widened.

Then, the contact plug 24 and the wire 22 are formed by a known method.

The semiconductor device illustrated in FIG. 15 in which the contact plug 24 is provided on the gate electrode 16 is manufactured by the above-mentioned manufacturing method.

In the manufacturing method according to the third embodiment, the gate electrode 16 is not exposed to anisotropic dry etching as in the manufacturing method according to the first embodiment. Therefore, it is possible to reduce etching damage to the gate electrode 16.

Furthermore, in the manufacturing method according to the third embodiment, the sidewall insulating film 40 is formed on the side surface of the contact hole 30. In a case in which wet etching is performed for the interlayer insulating layer 20 at the bottom of the contact hole 30, the contact hole 30 is not widened since the sidewall insulating film 40 is provided on the side surface of the contact hole 30. Therefore, the width of the contact plug 24 can be less than that in the first embodiment. As a result, for example, a short circuit between adjacent contact plugs 24 or a short circuit between adjacent wires is prevented.

As described above, according to the third embodiment, it is possible to achieve a semiconductor device that reduces etching damage to a gate electrode and a method for manufacturing the semiconductor device. In addition, the width of the contact plug 24 can be less than that in the first embodiment.

In the first and second embodiments, the case in which the second insulating film or the first insulating film functioning as the etching stopper is made of silicon nitride has been described as an example. However, for example, other materials, such as SiCN and SiCO, may be used instead of silicon nitride.

In the third embodiment, the case in which the sidewall insulating film is made of silicon nitride has been described as an example. However, for example, other materials, such as SiCN and SiCO, may be used instead of silicon nitride.

While certain embodiments have been described, these embodiments have been presented by way of example only, and are not intended to limit the scope of the inventions. Indeed, the semiconductor devices and the semiconductor device manufacturing methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
a gate electrode;
a conductive layer;
an insulating layer provided between the gate electrode and the conductive layer; and
a contact plug surrounded by the insulating layer, the contact plug connecting the gate electrode and the conductive layer, the contact plug including a first region and a second region, the second region being closer to the conductive layer than the first region, a width of the first region being greater than a width of the second region.

2. The semiconductor device according to claim 1,
wherein the first region contacts the gate electrode.

3. The semiconductor device according to claim 1,
wherein the insulating layer includes:
a first insulating film provided on the gate electrode;
a second insulating film provided on the first insulating film, a material forming the second insulating film being different from a material forming the first insulating film; and
a third insulating film provided on the second insulating film, a material forming the third insulating film being different from the material forming the second insulating film, and
the first region is surrounded by the first insulating film and the second region is surrounded by the second insulating film.

4. The semiconductor device according to claim 3,
wherein the first insulating film and the third insulating film are made of silicon oxide and the second insulating film is made of silicon nitride.

5. The semiconductor device according to claim 1,
wherein the insulating layer includes:
a first insulating film provided on the gate electrode; and
a second insulating film provided on the first insulating film, a material forming the second insulating film being different from a material forming the first insulating film, and
the first region is surrounded by the first insulating film and the second region is surrounded by the second insulating film.

6. The semiconductor device according to claim 5,
wherein the first insulating film is made of silicon nitride and the second insulating film is made of silicon oxide.

7. The semiconductor device according to claim 1, further comprising:
a sidewall insulating film provided between the second region and the insulating layer.

8. The semiconductor device according to claim 7,
wherein the insulating layer is made of silicon oxide and the sidewall insulating film is made of silicon nitride.

9. A method for manufacturing a semiconductor device, comprising:
forming a gate electrode;
forming a first insulating film on the gate electrode;
forming a second insulating film on the first insulating film, a material forming the second insulating film being different from a material forming the first insulating film;
forming a third insulating film on the second insulating film, a material forming the third insulating film being different from the material forming the second insulating film;
etching the third insulating film using anisotropic dry etching to form a contact hole, the second insulating film being exposed at a bottom of the contact hole;
removing the second insulating film at the bottom of the contact hole; and
removing the first insulating film at the bottom of the contact hole using wet etching such that the gate electrode is exposed.

10. The method for manufacturing a semiconductor device according to claim 9,
wherein the first insulating film and the third insulating film are made of silicon oxide and the second insulating film is made of silicon nitride.

11. A method for manufacturing a semiconductor device, comprising:
forming a gate electrode;
forming a first insulating film on the gate electrode;
forming a second insulating film on the first insulating film, a material forming the second insulating film being different from a material forming the first insulating film;
etching the second insulating flint using anisotropic dry etching to form a contact hole, the first insulating film being exposed at a bottom of the contact hole; and
removing the first insulating film at the bottom of the contact hole using wet etching such that the gate electrode is exposed.

12. The method for manufacturing a semiconductor device according to claim 11,
wherein the first insulating film is made of silicon nitride and the second insulating film is made of silicon oxide.

13. A method for manufacturing a semiconductor device, comprising:
forming a gate electrode;
forming an insulating layer on the gate electrode;
etching the insulating layer using anisotropic dry etching to form a contact hole such that a portion of the insulating layer remains between the contact hole and the gate electrode;
forming a sidewall insulating film on a side surface of the contact hole; and
removing a portion of the insulating layer at a bottom of the contact hole using wet etching such that the gate electrode is exposed.

14. The method for manufacturing a semiconductor device according to claim 13,
wherein the insulating layer is made of silicon oxide and the sidewall insulating film is made of silicon nitride.
